(19) United States
(12) Patent Application Publication
(10) Pub. No.: US 2026/0196174 A1
(43) Pub. Date: Jul. 9, 2026

(54) SUB-PIXEL AND DISPLAY DEVICE INCLUDING THE SUB-PIXEL, AND ELECTRONIC DEVICE INCLUDING THE DISPLAY DEVICE

(71) Applicant: Samsung Display Co., LTD., Yongin-si (KR)

(72) Inventors: Dong Woo KIM, Yongin-si (KR); Kyung Bae KIM, Yongin-si (KR); Yeon Kyung KIM, Yongin-si (KR); Yong Hee LEE, Yongin-si (KR)

(21) Appl. No.: 19/419,588

(22) Filed: Dec. 15, 2025

(30) Foreign Application Priority Data
Jan. 9, 2025 (KR) 10-2025-0003523

(51) Int. Cl. G09G 3/3233

(52) U.S. Cl. CPC G09G 3/3233; G09G 2300/0819; G09G 2320/0233

(57) ABSTRACT

A sub-pixel includes: a first transistor including a first electrode connected to a first power voltage node via a first node, a second electrode connected to a second node, and a gate electrode connected to a third node; a second transistor connected between a data line and a fourth node; a third transistor connected between the second node and the third node; a fourth transistor connected between the fourth node and an initialization voltage node; a first capacitor connected between the third node and the fourth node; and a second capacitor connected between the first node and the third node. The third transistor and the fourth transistor are simultaneously turned on and off. A turn-on period of the second transistor and a turn-on period of the third transistor do not overlap.

The application claims priority to Korean patent application No. 10-2025-0003523, filed on Jan. 9, 2025, and all the benefits accruing therefrom under 35 U.S.C. § 119, the content of which in its entirety is herein incorporated by reference.

### BACKGROUND

### 1. Field

The disclosure generally relates to a sub-pixel, a display device including the sub-pixel, and an electronic device.

### 2. Related Art

With the development of information technology, the importance of a display device as a medium of connection between a user and information is becoming increasingly important. In response to this, the use of display devices such as liquid crystal display devices and organic light-emitting display device, etc., is increasing.

Recently, sub-pixels applicable to high-resolution display panels are being desired.

### SUMMARY

Embodiments provide a sub-pixel applicable to a high-resolution panel, a display device having the same, and an electronic device.

In an embodiment of the disclosure, a sub-pixel includes a first transistor in which a first electrode is connected to a first power voltage node to which a first power voltage is input via a first node, a second electrode is connected to a second node, and a gate electrode is connected to a third node; a light-emitting element in which an anode electrode is connected to the second node and a cathode electrode is connected to a second power voltage node to which a second power voltage is input; a second transistor connected between a data line and a fourth node, the second transistor including a gate electrode connected to a first sub-gate line; a third transistor connected between the second node and the third node, the third transistor including a gate electrode connected to a second sub-gate line; a fourth transistor connected between the fourth node and an initialization voltage node to which an initialization voltage is input, the fourth transistor including a gate electrode connected to a third sub-gate line; a first capacitor connected between the third node and the fourth node; and a second capacitor connected between the first node and the third node. The third transistor and the fourth transistor may be simultaneously turned on and off. A turn-on period of the second transistor and a turn-on period of the third transistor may not overlap.

In an embodiment, the second sub-gate line and the third sub-gate line may be the same line.

In an embodiment, the sub-pixel may further include a fifth transistor connected between the anode electrode of the light-emitting element and the initialization voltage node, the fifth transistor including a gate electrode connected to a fourth sub-gate line; and a sixth transistor connected between the anode electrode of the light-emitting element and the second node, the sixth transistor including a gate electrode connected to an emission control line.

In an embodiment, the first transistor, the second transistor, the third transistor, the fourth transistor, and the sixth transistor may be a P-type transistor. The fifth transistor may be an N-type transistor.

In an embodiment, each of the first transistor to the sixth transistor may include a body electrode. The first power voltage may be supplied to the body electrode of the first transistor, the body electrode of the second transistor, the body electrode of the third transistor, the body electrode of the fourth transistor, and the body electrode of the sixth transistor. The initialization voltage may be supplied to the body electrode of the fifth transistor.

In an embodiment, one horizontal period may be divided into a first period, a second period, and a third period. The second transistor may be turned on during the third period. The third transistor and the fourth transistor may be turned on during the first period and the second period. The fifth transistor may be turned on during the first period, the second period, and the third period. The sixth transistor may be turned on during the first period.

In an embodiment, a data signal may be supplied to the data line during the third period.

In an embodiment, the sub-pixel may further include a seventh transistor connected between the second node and the sixth transistor, the seventh transistor including a gate electrode connected to a common line and a body electrode to which the first power voltage is input. The seventh transistor may be a P-type transistor. The seventh transistor may be maintained in a turn-on state.

In an embodiment, the sub-pixel may further include a seventh transistor connected between the first power voltage node and the first node, the seventh transistor including a gate electrode connected to the first node and a body electrode to which the first power voltage is input. The seventh transistor may be a P-type transistor.

In an embodiment, the first power voltage may be set to a voltage higher than the second power voltage. The initialization voltage may be a voltage at which the light-emitting element is turned off when supplied to the anode electrode of the light-emitting element.

By embodiments of the disclosure, a display device includes sub-pixels connected with data lines, gate lines, and emission control lines; a gate driver configured to drive the gate lines and the emission control lines; and a data driver configured to drive the data lines. At least one of the sub-pixels may include a first transistor in which a first electrode is connected to a first power voltage node to which a first power voltage is input via a first node, a second electrode is connected to a second node, and a gate electrode is connected to a third node; a light-emitting element in which an anode electrode is connected to the second node and a cathode electrode is connected to a second power voltage node to which a second power voltage is input; a second transistor connected between a data line which is one of the data lines and a fourth node, the second transistor being turned on when an enable first scan signal is supplied to a first sub-gate line which is one of the gate lines; a third transistor connected between the second node and the third node, the third transistor being turned on when an enable second scan signal is supplied to a second sub-gate line which is one of the gate lines; a fourth transistor connected between the fourth node and an initialization voltage node to which an initialization voltage is input, the fourth transistor being turned on when an enable third scan signal is supplied to a third sub-gate line which is one of the gate lines; a fifth transistor connected between the anode electrode of the light-emitting element and the initialization voltage node, the fifth transistor being turned on when an enable fourth scan signal is supplied to a fourth sub-gate line which is one of the gate lines; a sixth transistor connected between the anode electrode of the light-emitting element and the second node, the sixth transistor being turned off when a disable emission control signal is supplied to an emission control line which is one of the emission control lines; a first capacitor connected between the third node and the fourth node; and a second capacitor connected between the first node and the third node.

In an embodiment, the second sub-gate line and the third sub-gate line may be the same line.

In an embodiment, the first transistor, the second transistor, the third transistor, the fourth transistor, and the sixth transistor may be a P-type transistor. The fifth transistor may be an N-type transistor.

In an embodiment, each of the first transistor to the sixth transistor may include a body electrode. The first power voltage may be supplied to the body electrode of the first transistor, the body electrode of the second transistor, the body electrode of the third transistor, the body electrode of the fourth transistor, and the body electrode of the sixth transistor. The initialization voltage may be supplied to the body electrode of the fifth transistor.

In an embodiment, one horizontal period may be divided into a first period, a second period, and a third period. The gate driver may supply the enable first scan signal to the first sub-gate line during the third period. The gate driver may supply the enable second scan signal to the second sub-gate line during the first period and the second period, and may supply the enable third scan signal to the third sub-gate line during the first period and the second period. The gate driver may supply the enable fourth scan signal to the fourth sub-gate line during the first period, the second period, and the third period. The gate driver may supply the disable emission control signal to the emission control line during the second period and the third period.

In an embodiment, the data driver may supply a data signal to the data line during the third period.

In an embodiment, the display device may further include a seventh transistor connected between the second node and the sixth transistor, the seventh transistor including a gate electrode connected to a common line and a body electrode to which the first power voltage is input. The seventh transistor may be a P-type transistor. The seventh transistor may be maintained in a turn-on state by a control signal supplied to the common line.

In an embodiment, the common line may be commonly connected to the sub-pixels.

In an embodiment, the display device may further include a seventh transistor connected between the first power voltage node and the first node, the seventh transistor including a gate electrode connected to the first node and a body electrode to which the first power voltage is input. The seventh transistor may be a P-type transistor.

By embodiments of the disclosure, an electronic device includes a processor; a display module configured to display an image based on input image data supplied from the processor; a memory in which data information desired for an operation of the processor is stored; and a power module configured to generate power desired for driving. The display module may includes sub-pixels connected with data lines, gate lines, and emission control lines; a gate driver configured to drive the gate lines and the emission control lines; and a data driver configured to drive the data lines. At least one of the sub-pixels may include a first transistor in which a first electrode is connected to a first power voltage node to which a first power voltage is input via a first node, a second electrode is connected to a second node, and a gate electrode is connected to a third node; a light-emitting element in which an anode electrode is connected to the second node and a cathode electrode is connected to a second power voltage node to which a second power voltage is input; a second transistor connected between a data line which is one of the data lines and a fourth node, the second transistor being turned on when an enable first scan signal is supplied to a first sub-gate line which is one of the gate lines; a third transistor connected between the second node and the third node, the third transistor being turned on when an enable second scan signal is supplied to a second sub-gate line which is one of the gate lines; a fourth transistor connected between the fourth node and an initialization voltage node to which an initialization voltage is input, the fourth transistor being turned on when an enable third scan signal is supplied to a third sub-gate line which is one of the gate lines; a fifth transistor connected between the anode electrode of the light-emitting element and the initialization voltage node, the fifth transistor being turned on when an enable fourth scan signal is supplied to a fourth sub-gate line which is one of the gate lines; a sixth transistor connected between the anode electrode of the light-emitting element and the second node, the sixth transistor being turned off when a disable emission control signal is supplied to an emission control line which is one of the emission control lines; a first capacitor connected between the third node and the fourth node; and a second capacitor connected between the first node and the third node.

### BRIEF DESCRIPTION OF THE DRAWINGS

Embodiments will now be described more fully hereinafter with reference to the accompanying drawings.

FIG. 1 is a block diagram of an embodiment of a display device according to the disclosure.

FIG. 2 is a block diagram illustrating some embodiments of one of the sub-pixels of FIG. 1.

FIG. 3 is a diagram illustrating some embodiments of the gate driver for driving the sub-pixels shown in FIG. 2.

FIG. 4 is a circuit diagram illustrating some embodiments of the sub-pixel shown in FIG. 2.

FIG. 5 is a waveform diagram illustrating an embodiment of a method of driving the sub-pixel shown in FIG. 4.

FIGS. 6A to 6D are diagrams illustrating an operation process of a sub-pixel corresponding to the driving waveform of FIG. 5.

FIG. 7 is a circuit diagram illustrating an embodiment of the sub-pixel shown in FIG. 2.

FIG. 8 is a circuit diagram illustrating an embodiment of the sub-pixel shown in FIG. 2.

FIG. 9 is a plan view illustrating an embodiment of the display panel of FIG. 1.

FIG. 10 is a plan view illustrating another embodiment of one of the pixels of FIG. 9.

FIG. 11 is a plan view illustrating another embodiment of one of the pixels of FIG. 9.

FIG. 12 is a block diagram illustrating an embodiment of an electronic device in accordance with the disclosure.

FIG. 13 shows schematic views of various embodiments of an electronic device.

### DETAILED DESCRIPTION

Hereinafter, features of some embodiments are described in more detail with reference to the accompanying drawings so that those skilled in the art may easily practice the disclosure. The disclosure may be implemented in various different forms and is not limited to the disclosed embodiments described in the specification. Illustrative embodiments may be embodied in different forms and should not be construed as limited to the embodiments set forth herein. Rather, these embodiments are provided so that this disclosure will be thorough and complete, and will fully convey the scope of the embodiments to those skilled in the art.

A part irrelevant to the description will be omitted to clearly describe the disclosure, and the same or similar constituent elements will be designated by the same reference numerals throughout the specification. Therefore, the same reference numerals may be used in different drawings to identify the same or similar elements. In the drawing figures, dimensions may be exaggerated for clarity of illustration. It will be understood that when an element is referred to as being “between” two elements, it may be the only element between the two elements, or one or more intervening elements may also be present. Like reference numerals refer to like elements throughout.

In description, the expression “equal” may mean “substantially equal.” That is, this may mean equality to a degree to which those skilled in the art may understand the equality. Other expressions may be expressions in which “substantially’ is omitted.

Some embodiments are described in the accompanying drawings in relation to functional block, unit, and/or module. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the disclosure. In addition, in some embodiments, the block, unit and/or module may be physically combined into more complex blocks, units, and/or modules without departing from the scope of the disclosure.

The term “connection” between two components may include both electrical connection and physical connection, but the disclosure is not necessarily limited thereto. For example, the term “connection” used based on circuit diagrams may mean electrical connection, and the term “connection” used based on cross-sectional and plan views may mean physical connection.

It will be understood that, although the terms “first,” “second,” etc. may be used herein to describe various elements, these elements should not be limited by these terms. These terms are only used to distinguish one element from another element. Thus, a “first” element discussed below could also be termed a “second” element without departing from the teachings of the disclosure.

The disclosure is not limited to embodiments disclosed below, and may be implemented in various forms. Each embodiment disclosed below may be independently embodied or be combined with at least another embodiment prior to being embodied.

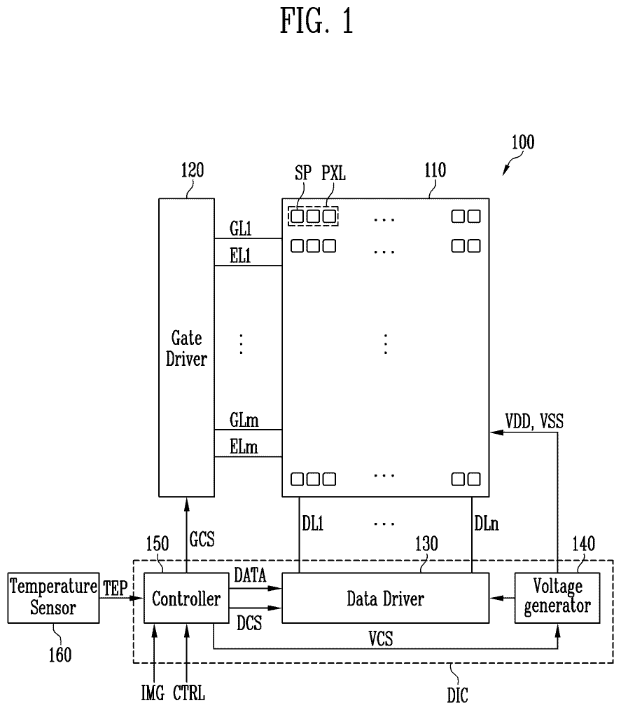

FIG. 1 is a block diagram of an embodiment of a display device according to the disclosure.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm where m is a natural number. The sub-pixels SP may be connected to the data driver 130 through first to n-th data lines DL1 to DLn where n is a natural number.

Each of the sub-pixels SP may include at least one light-emitting element configured to generate light. Accordingly, each of the sub-pixels SP may generate light of a particular color, such as red, green, blue, cyan, magenta, and yellow. Two or more of the sub-pixels SP may form a single pixel PXL. In an embodiment, the pixel PXL may include three sub-pixels, as shown in FIG. 1, for example.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating the start of each frame, a horizontal synchronization signal for outputting scan signals in synchronization with the timing at which data signals are applied, or the like.

In embodiments, first to m-th emission control lines EL1 to ELm connected to the sub-pixels SP in a row direction may be further provided. In this case, the gate driver 120 may include an emission control driver configured to control the first to m-th emission control lines EL1 to ELm. The emission control driver may operate under the control of the controller 150.

The gate driver 120 may be disposed on one side of the display panel 110. However, the disclosure is not limited thereto. In an embodiment, the gate driver 120 may be divided into two or more physically and/or logically separated drivers, and the drivers may be disposed on one side of the display panel 110 and an opposite side of the display panel 110 opposite to the one side, for example. As described above, the gate driver 120 may be disposed around the display panel 110 in various forms in the embodiments.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, or the like.

The data driver 130 may use voltages from the voltage generator 140 to apply data signals having grayscale voltages corresponding to the image data DATA to the first to n-th data lines DL1 to DLn. In case that a gate signal is applied to each of the first to m-th gate lines GL1 to GLm, data signals corresponding to the image data DATA may be applied to the first to n-th data lines DL1 to DLn. Accordingly, the corresponding sub-pixels SP may generate light corresponding to the data signals. Accordingly, an image may be displayed on the display panel 110.

In embodiments, the gate driver 120 and the data driver 130 may include complementary metal-oxide semiconductor (“CMOS”) circuit elements.

The voltage generator 140 may operate in response to a voltage control signal VCS from the controller 150. The voltage generator 140 may generate a plurality of voltages and provide the generated voltages to constituent elements of the display device 100. In an embodiment, the voltage generator 140 may generate a plurality of voltages by receiving an input voltage from the outside of the display device 100, adjusting the received voltage, and regulating the adjusted voltage, for example.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the first power voltage VDD. In other embodiments, the first power voltage VDD or the second power voltage VSS may be provided by an external device of the display device 100.

In addition, the voltage generator 140 may generate various voltages. In an embodiment, the voltage generator 140 may generate an initialization voltage applied to the sub-pixels SP, for example.

The controller 150 may control various operations of the display device 100. The controller 150 may receive input image data IMG and a control signal CTRL for controlling the display of the input image data, from the outside. The controller 150 may provide the gate control signal GCS, the data control signal DCS, and the voltage control signal VCS in response to the control signal CTRL.

The controller 150 may convert the input image data IMG to be suitable for the display device 100 or the display panel 110 to output the image data DATA. In embodiments, the controller 150 may output the image data DATA by aligning the input image data IMG to be suitable for the sub-pixels SP of a row unit.

Two or more components of the data driver 130, the voltage generator 140, and the controller 150 may be disposed (e.g., mounted) on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separate components within one driver integrated circuit DIC. In other embodiments, at least one of the data driver 130, the voltage generator 140, and the controller 150 may be provided as a component separated from the driver integrated circuit DIC.

The display device 100 may include at least one temperature sensor 160. The temperature sensor 160 may sense a surrounding temperature and generate temperature data TEP representing the sensed temperature. In embodiments, the temperature sensor 160 may be next (adjacent) to the display panel 110 and/or the driver integrated circuit DIC.

The controller 150 may control various operations of the display device 100 in response to the temperature data TEP. In embodiments, the controller 150 may adjust the luminance of an image outputted from the display panel 110 in response to the temperature data TEP. In an embodiment, the controller 150 may control the data signals and the first and second power voltages VDD and VSS by controlling components such as the data driver 130 and/or the voltage generator 140, for example.

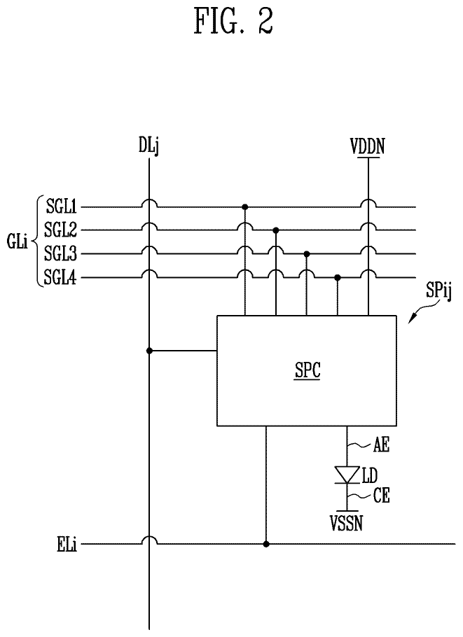

FIG. 2 is a block diagram illustrating some embodiments of one of the sub-pixels of FIG. 1. In FIG. 2, among the sub-pixels SP of FIG. 1, a sub-pixel SPij disposed in an i-th row (i is an integer greater than or equal to 1 and less than or equal to m) and a j-th column (j is an integer greater than or equal to 1 and less than or equal to n) is illustrated as an example.

Referring to FIG. 2, the sub-pixel SPij may include a sub-pixel circuit SPC and a light-emitting element LD.

The light-emitting element LD may be connected between a first power voltage node VDDN and a second power voltage node VSSN. In this case, the first power voltage node VDDN may be a node that transmits the first power voltage VDD of FIG. 1, and the second power voltage node VSSN may be a node that transmits the second power voltage VSS of FIG. 1.

An anode electrode AE of the light-emitting element LD may be connected to the first power voltage node VDDN through the sub-pixel circuit SPC, and a cathode electrode CE of the light-emitting element LD may be connected to the second power voltage node VSSN. In an embodiment, the anode electrode AE of the light-emitting element LD may be connected to the first power voltage node VDDN through one or more transistors included in the sub-pixel circuit SPC, for example.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC may control the light-emitting element LD according to signals received through these signal lines.

The sub-pixel circuit SPC may operate in response to a scan signal received through the i-th gate line GLi. The i-th gate line GLi may include one or more sub-gate lines. In embodiments, as shown in FIG. 2, the i-th gate line GLi may include a first sub-gate line SGL1, a second sub-gate line SGL2, a third sub-gate line SGL3, and a fourth sub-gate line SGL4.

The sub-pixel circuit SPC may operate in response to scan signals received through the first sub-gate line SGL1 to the fourth sub-gate line SGL4. In case that the i-th gate line GLi includes two or more sub-gate lines, the sub-pixel circuit SPC may operate in response to scan signals received through the corresponding sub-gate lines.

The sub-pixel circuit SPC may operate in response to an emission control signal received through the i-th emission control line ELi. In embodiments, the i-th emission control line ELi may include one or more sub-emission control lines. In case that the i-th emission control line ELi includes two or more sub-emission control lines, the sub-pixel circuit SPC may operate in response to emission control signals received through the corresponding sub-emission control lines.

The sub-pixel circuit SPC may receive a data signal through the j-th data line DLj. The sub-pixel circuit SPC may store a voltage corresponding to the data signal in response to at least one of the scan signals received through the first sub-gate line SGL1 to the fourth sub-gate line SGL4. In response to the emission control signal received through the i-th emission control line ELi, the sub-pixel circuit SPC may adjust the current flowing from the first power voltage node VDDN to the second power voltage node VSSN through the light-emitting element LD according to the stored voltage. Accordingly, the light-emitting element LD may generate light of luminance corresponding to the data signal.

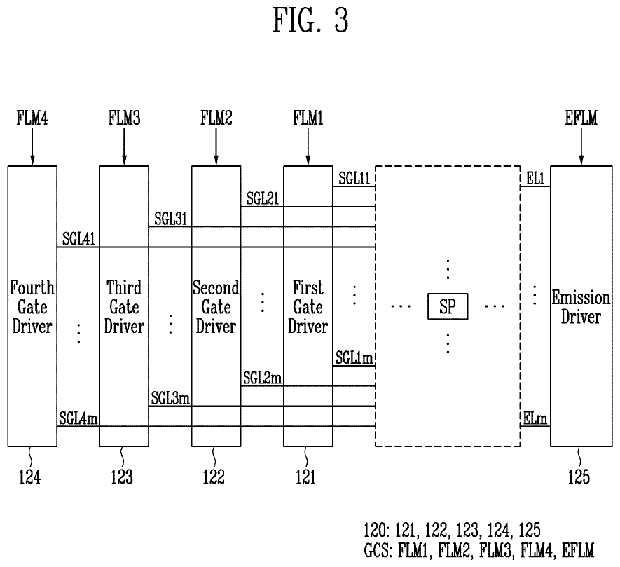

FIG. 3 is a diagram illustrating some embodiments of the gate driver for driving the sub-pixels shown in FIG. 2. The gate control signal GCS may include a first scan start signal FLM1, a second scan start signal FLM2, a third scan start signal FLM3, a fourth scan start signal FLM4, and an emission start signal EFLM. The gate control signal GCS may further include clock signals.

Referring to FIG. 3, the gate driver 120 may include a first gate driver 121, a second gate driver 122, a third gate driver 123, a fourth gate driver 124, and an emission driver 125. The first gate driver 121 to the fourth gate driver 124 may be functionally separated. At least two gate drivers may be integrated into a single gate driver.

The first gate driver 121 may receive the first scan start signal FLM1 and generate a first scan signal by shifting the first scan start signal FLM1 in response to a clock signal. The first gate driver 121 may sequentially supply the first scan signal to first sub-gate lines SGL11 to SGL1m.

The second gate driver 122 may receive the second scan start signal FLM2 and generate a second scan signal by shifting the second scan start signal FLM2 in response to a clock signal. The second gate driver 122 may sequentially supply the second scan signal to second sub-gate lines SGL21 to SGL2m.

The third gate driver 123 may receive the third scan start signal FLM3 and generate a third scan signal by shifting the third scan start signal FLM3 in response to a clock signal. The third gate driver 123 may sequentially supply the third scan signal to third sub-gate lines SGL31 to SGL3m.

The fourth gate driver 124 may receive the fourth scan start signal FLM4 and generate a fourth scan signal by shifting the fourth scan start signal FLM4 in response to a clock signal. The fourth gate driver 124 may sequentially supply the fourth scan signal to fourth sub-gate lines SGL41 to SGL4m.

The first scan signal, the second scan signal, the third scan signal, and the fourth scan signal may have a gate-on voltage such that transistors included in the sub-pixels SP may be turned on. The first scan signal, the second scan signal, the third scan signal, and the fourth scan signal having the gate-on voltage may be respectively referred to as an enable first scan signal, an enable second scan signal, an enabled third scan signal, and an enable fourth scan signal.

In an embodiment, a logic low-level voltage as an enable scan signal may be supplied to a P-type transistor, and a logic high-level voltage as an enable scan signal may be supplied to an N-type transistor, for example. In embodiments, the enable first scan signal, the enable second scan signal, and the enable third scan signal may be set to the logic low-level, and the enable fourth scan signal may be set to the logic high-level.

In addition, gate drivers 121 to 124 may supply a disable scan signal to the sub-gate lines SGL11 to SGL1m, SGL21 to SGL2m, SGL31 to SGL3m, and SGL41 to SGL4m during a period when the enable scan signal is not supplied. The disable scan signal may be set to a gate-off voltage such that the transistors included in the sub-pixels SP may be turned off.

The first sub-gate line SGL1 shown in FIG. 2 may be one of the first sub-gate lines SGL11 to SGL1m. The second sub-gate line SGL2 shown in FIG. 2 may be one of the second sub-gate lines SGL21 to SGL2m. The third sub-gate line SGL3 shown in FIG. 2 may be one of the third sub-gate lines SGL31 to SGL3m. The fourth sub-gate line SGL4 shown in FIG. 2 may be one of the fourth sub-gate lines SGL41 to SGL4m.

The emission driver 125 may generate an emission control signal by shifting the emission start signal EFLM in response to a clock signal. The emission driver 125 may sequentially supply the emission control signal to emission control lines EL1 to ELm. The emission control signal may be set to a gate-off voltage such that the transistors included in the sub-pixels SP may be turned off. The emission control signal having the gate-off voltage may be also referred to as a disable emission control signal.

In an embodiment, a logic high-level voltage as a disable emission control signal may be supplied to the P-type transistor, and a logic low-level voltage as a disable emission control signal may be supplied to the N-type transistor, for example. In embodiments, the disable emission control signal may be set to the logic high-level.

The emission driver 125 may be supply an enable emission control signal to the emission control lines EL1 to ELm during a period when the disable emission control signal is not supplied. The enable emission control signal may be set to a gate-on voltage such that the transistors included in the sub-pixels SP may be turned on.

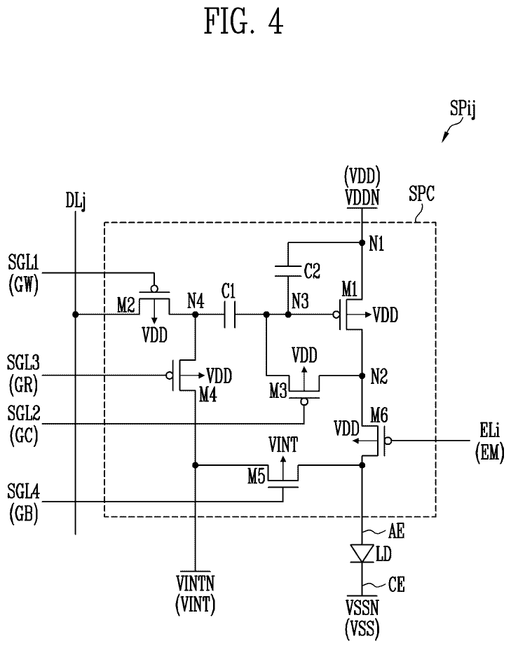

FIG. 4 is a circuit diagram illustrating some embodiments of the sub-pixel shown in FIG. 2.

Referring to FIG. 4, the sub-pixel SPij may include a sub-pixel circuit SPC and a light-emitting element LD.

The light-emitting element LD may include an anode electrode AE, a cathode electrode CE, and a light-emitting layer. The light-emitting layer may be disposed between the anode electrode AE and the cathode electrode CE. The anode electrode AE of the light-emitting element LD may be electrically connected to a first power voltage node VDDN via a second node N2, a first transistor M1, and a first node N1. The cathode electrode CE may be electrically connected to a second power voltage node VSSN. The light-emitting element LD may generate light of a set luminance corresponding to the amount of current supplied form the first power voltage node VDDN to the second power voltage node VSSN via the sub-pixel circuit SPC.

The light-emitting element LD may be selected as an organic light-emitting diode. Further, the light-emitting element LD may be selected as an inorganic light-emitting diode, such as a micro light-emitting diode (“LED”), a quantum dot light-emitting diode, or the like. In addition, the light-emitting element LD may also be an element composed of a combination of organic and inorganic materials. In FIG. 4, the sub-pixel SPij is shown as including a single light-emitting element LD, but in other embodiments, the sub-pixel SPij may include a plurality of light-emitting elements LD, and the plurality of light-emitting elements LD may be connected in series, parallel, or series-parallel with each other.

The sub-pixel circuit SPC may include the first transistor M1, a second transistor M2, a third transistor M3, a fourth transistor M4, a fifth transistor M5, a sixth transistor M6, a first capacitor C1, and a second capacitor C2.

The first transistor M1 to the sixth transistor M6 may be a metal oxide silicon field effect transistor (“MOSFET”) having a body electrode. In this case, the first transistor M1 to the sixth transistor M6 may be mountable in a narrow area. Accordingly, the sub-pixel SPij may be applied to a high-resolution panel.

In embodiments, the first transistor M1 to the fourth transistor M4, and the sixth transistor M6 may be a P-type transistor, the fifth transistor M5 may be an N-type transistor. A first power voltage VDD may be supplied to the body electrode of the first transistor M1, the body electrode of the second transistor M2, the body electrode of the third transistor M3, the body electrode of the fourth transistor M4, and the body electrode of the sixth transistor M6. An initialization voltage VINT may be supplied to the body electrode of the fifth transistor M5.

A first electrode of the first transistor M1 may be connected to the first node N1, and a second electrode of the first transistor M1 may be connected to the second node N2. Here, “connected” may include the meaning of electrically connected. A gate electrode of the first transistor M1 may be connected to a third node N3. The first node N1 may be a node connected to the first power voltage node VDDN, and the second node N2 may be a node to which the anode electrode AE of the light-emitting element LD is connected via the sixth transistor M6. The first transistor M1 may control the amount of driving current flowing from the first power voltage node VDDN to the second power voltage node VSSN via the light-emitting element LD in response to a voltage of the third node N3.

The second transistor M2 may be connected between a data line DLj and a fourth node N4. A gate electrode of the second transistor M2 may be electrically connected to a first sub-gate line SGL1. The second transistor M2 may be turned on when an enable first scan signal GW is supplied to the first sub-gate line SGL1, thereby electrically connecting the data line DLj and the fourth node N4.

The third transistor M3 may be electrically connected between the second node N2 and the third node N3. A gate electrode of the third transistor M3 may be connected to a second sub-gate line SGL2. The third transistor M3 may be turned on when an enable second scan signal GC is supplied to the second sub-gate line SGL2, thereby electrically connecting the second node N2 and the third node N3. When the second node N2 and the third node N3 are electrically connected, the first transistor M1 may be connected in the form of a diode.

The fourth transistor M4 may be connected between the fourth node N4 and an initialization voltage node VINTN. A gate electrode of the fourth transistor M4 may be electrically connected to a third sub-gate line SGL3. The fourth transistor M4 may be turned on when an enable third scan signal GR is supplied to the third sub-gate line SGL3, thereby electrically connecting the fourth node N4 and the initialization voltage node VINTN.

The initialization voltage node VINTN may transmit the initialization voltage VINT. The initialization voltage VINT may be supplied by the voltage generator 140 shown in FIG. 1. The initialization voltage VINT may be set to a voltage at which the light-emitting element LD is turned off when the initialization voltage VINT is supplied to the anode electrode AE of the light-emitting element LD.

The fifth transistor M5 may be connected between the initialization voltage node VINTN and the anode electrode AE of the light-emitting element LD. A gate electrode of the fifth transistor M5 may be electrically connected to a fourth sub-gate line SGL4. The fifth transistor M5 may be turned on when an enable fourth scan signal GB is supplied to the fourth sub-gate line SGL4, thereby electrically connecting the initialization voltage node VINTN and the anode electrode AE of the light-emitting element LD.

The sixth transistor M6 may be connected between the second node N2 and the anode electrode AE of the light-emitting element LD. A gate electrode of the sixth transistor M6 may be electrically connected to an emission control line ELi. The sixth transistor M6 may be turned off when a disable emission control signal EM is supplied to the emission control line ELi, and may be turned on when an enable emission control signal EM is supplied to the emission control line ELi. When the sixth transistor M6 is turned off, an electrical connection between the second node N2 and the light-emitting element LD may be turned off, and the light-emitting element LD may be set to a non-emitting state accordingly.

The first capacitor C1 may be connected between the third node N3 and the fourth node N4. The first capacitor C1 may be a coupling capacitor. The first capacitor C1 may transmit a voltage change amount of the fourth node N4 to the third node N3.

The second capacitor C2 may be connected between the first node N1 and the third node N3. The second capacitor C2 may store a voltage between the first node N1 and the third node N3.

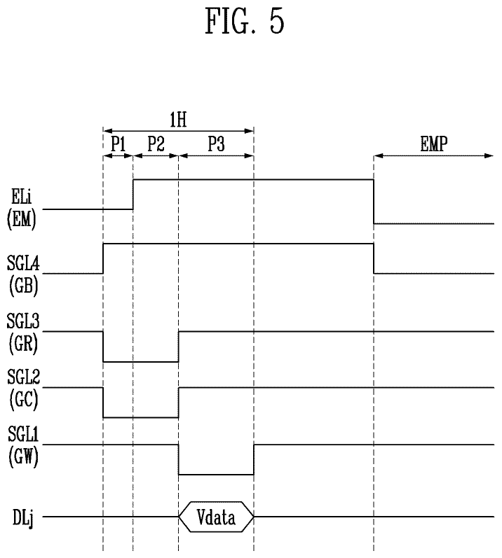

FIG. 5 is a waveform diagram illustrating an embodiment of a method of driving the sub-pixel shown in FIG. 4.

Referring to FIG. 5, one horizontal period 1H during which a data signal is supplied to the sub-pixel SPij may be divided into a first period P1, a second period P2, and a third period P3.

The data driver 130 may supply a data signal Vdata to the data line DLi during the third period P3. The data signal Vdata may have a set voltage within the voltage range of the data signal in response to a grayscale.

The gate driver 120 (or the first gate driver 121) may supply the enable first scan signal GW to the first sub-gate line SGL1 during the third period P3. Then, the second transistor M2 may be turned on during the third period P3.

The gate driver 120 (or the second gate driver 122) may supply the enable second scan signal GC to the second sub-gate line SGL2 during the first period P1 and the second period P2. Then, the third transistor M3 may be turned on during the first period P1 and the second period P2.

The gate driver 120 (or the third gate driver 123) may supply the enable third scan signal GR to the third sub-gate line SGL3 during the first period P1 and the second period P2. Then, the fourth transistor M4 may be turned on during the first period P1 and the second period P2. In an embodiment, the fourth transistor M4 may be turned on and off simultaneously with the third transistor M3, for example. The turn-on period of the fourth transistor M4 may not overlap with that of the second transistor M2.

The third sub-gate line SGL3 may be replaced by the second sub-gate line SGL2. In an embodiment, the third sub-gate line SGL3 may be the second sub-gate line SGL2, for example. In this case, the third gate driver 123 may be omitted and replaced with the second gate driver 122.

The gate driver 120 (or the fourth gate driver 124) may supply the enable fourth scan signal GB to the fourth sub-gate line SGL4 during the first period P1 to the third period P3. Then, the fifth transistor M5 may be turned on during the first period P1 to the third period P3.

The emission driver 125 may supply the disable emission control signal EM to the emission control line ELi during the second period P2 and the third period P3. Then, the sixth transistor M6 may be turned off during the second period P2 and the third period P3.

Further, during an emission period EMP after the third period P3, the emission driver 125 may supply the enable emission control signal EM to the emission control line ELi. Then, the sixth transistor M6 may be turned on during the emission period EMP.

The first period P1 may be a period during which the anode electrode AE of the light-emitting element LD, the third node N3, and the fourth node N4 are initialized. In an embodiment, the first period P1 may be an initialization period, for example.

The second period P2 may be a period for compensating for a threshold voltage of the first transistor M1. In an embodiment, the second period P2 may be a threshold voltage compensation period, for example.

The third period P3 may be a period in which a voltage of the data signal is stored in the first capacitor C1 and the second capacitor C2. In an embodiment, the third period P3 may be a writing period, for example.

The emission period EMP may be a period during which the light-emitting element LD emits light corresponding to the voltage of the data signal.

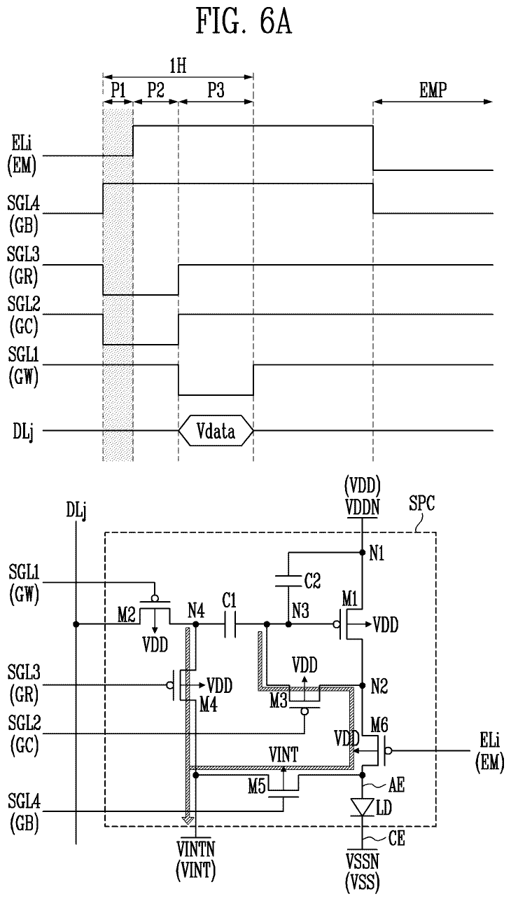

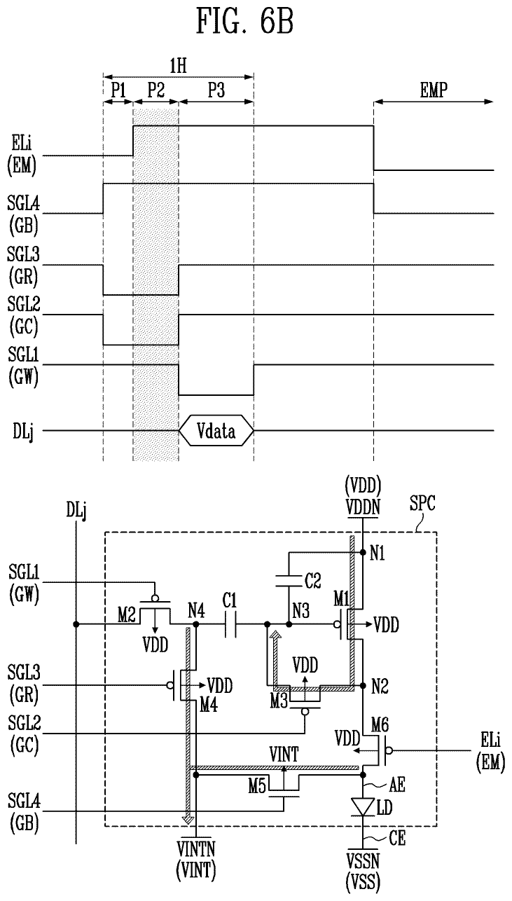

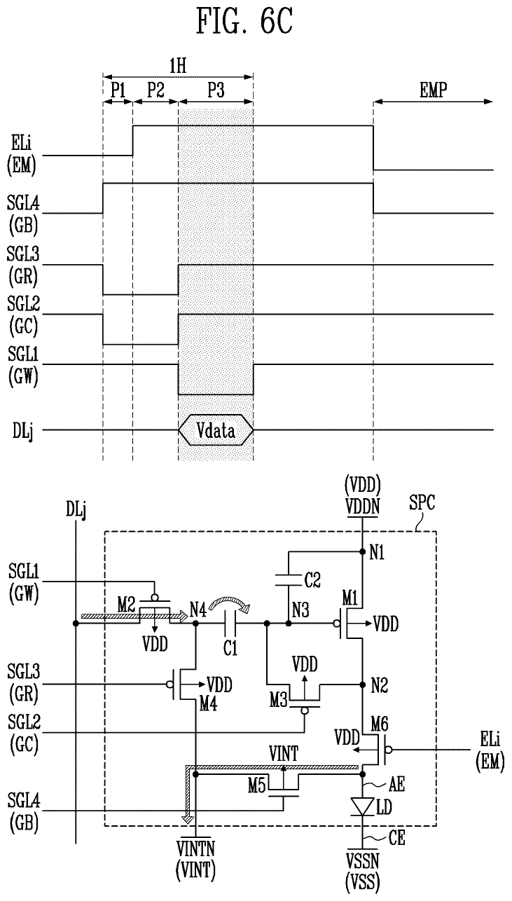

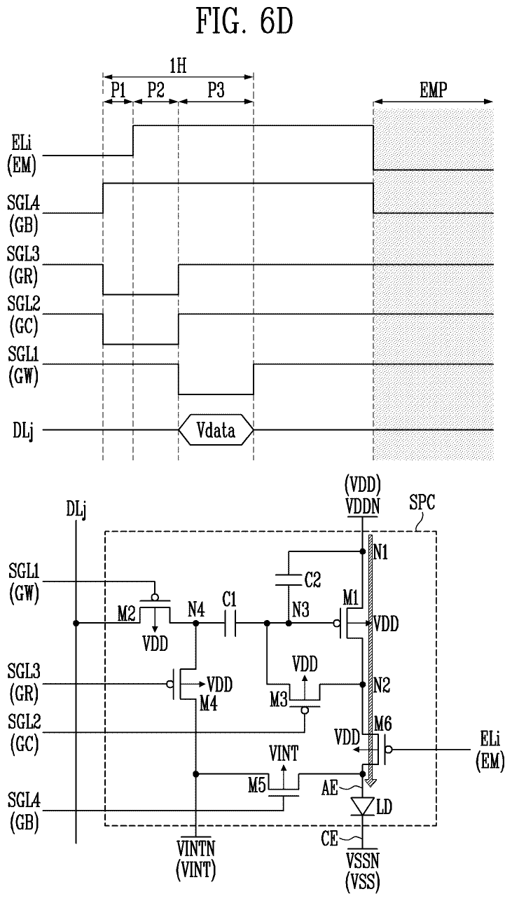

FIGS. 6A to 6D are diagrams illustrating an operation process of a sub-pixel corresponding to the driving waveform of FIG. 5.

Referring to FIG. 6A, during the first period P1, the enable second scan signal GC may be supplied to the second sub-gate line SGL2, and the enable third scan signal GR may be supplied to the third sub-gate line SGL3. In addition, during the first period P1, the enable fourth scan signal GB may be supplied to the fourth sub-gate line SGL4, and the enable emission signal EM may be supplied to the emission control line ELi.

When the enable second scan signal GC is supplied to the second sub-gate line SGL2, the third transistor M3 may be turned on. When the enable fourth scan signal GB is supplied to the fourth sub-gate line SGL4, the fifth transistor M5 may be turned on. When the enable emission control signal EM is supplied to the emission control line ELi, the sixth transistor M6 may be turned on.

In this case, during the first period P1, the initialization voltage VINT from the initialization voltage node VINTN may be supplied to the third node N3 via the fifth transistor M5, the anode electrode AE of the light-emitting element LD, the sixth transistor M6, the second node N2, and the third transistor M3. Accordingly, during the first period P1, the third node N3 may be initialized with the initialization voltage VINT.

When the enable third scan signal GR is supplied to the third sub-gate line SGL3, the fourth transistor M4 may be turned on. When the fourth transistor M4 is turned on, the initialization voltage VINT from the initialization voltage node VINTN may be supplied to the fourth node N4. Thus, during the first period P1, the fourth node N4 may be initialized with the initialization voltage VINT.

As described above, during the first period P1, the third node N3 and the fourth node N4 may be initialized with the initialization voltage VINT irrespective of the data signal supplied during the previous frame period.

When the initialization voltage VINT is supplied to the anode electrode AE of the light-emitting element LD, a voltage remaining in a parasitic capacitor of the light-emitting element LD may be discharged. The black expression ability of the display device 100 may be improved accordingly. In addition, the initialization voltage VINT may be set to a voltage at which the light-emitting element LD is not emitted. Accordingly, the light-emitting element LD may be set to a non-emitting state during the first period P1.

The initialization voltage may be supplied to the anode electrode AE of the light-emitting element LD via the fifth transistor M5 set to the N-type transistor. In this case, a gate-source voltage of the fifth transistor M5 may be kept constant regardless of the voltage change of the anode electrode AE of the light-emitting element LD. Accordingly, the voltage of the anode electrode AE of the light-emitting element LD may be stably reduced to the initialization voltage VINT.

In an embodiment, when the fifth transistor M5 is set to the P-type transistor, the gate-source voltage of the fifth transistor M5 may be changed in response to a change in the voltage of the anode electrode AE of the light-emitting element LD, for example. In this case, the anode electrode AE of the light-emitting element LD may not be reduced to the initialization voltage VINT.

Referring to FIG. 6B, during the second period P2, the enable second scan signal GC may be supplied to the second sub-gate line SGL2, and the enable third scan signal GR may be supplied to the third sub-gate line SGL3. In addition, during the second period P2, the enable fourth scan signal GB may be supplied to the fourth sub-gate line SGL4, and the disable emission control signal EM may be supplied to the emission control line ELi.

When the enable fourth scan signal GB is supplied to the fourth sub-gate line SGL4, the fifth transistor M5 may be turned on. When the fifth transistor M5 is turned on, the initialization voltage VINT may be supplied to the anode electrode AE of the light-emitting element LD. Accordingly, the light-emitting element LD may be set to a non-emitting state.

When the disable emission control signal EM is supplied to the emission control line ELi, the sixth transistor M6 may be turned off. When the sixth transistor M6 is turned off, the second node N2 and the anode electrode AE of the light-emitting element LD may be electrically cut off.

When the enable third scan signal GR is supplied to the third sub-gate line SGL3, the fourth transistor M4 may be turned on. When the fourth transistor M4 is turned on, the initialization voltage VINT may be supplied to the fourth node N4.

When the enable second scan signal GC is supplied to the second sub-gate line SGL2, the third transistor M3 may be turned on. When the third transistor M3 is turned on, the first transistor M1 may be connected in the form of a diode. In this case, the first power voltage VDD supplied form the first power voltage node VDDN may be supplied to the third node N3 via the first transistor M1 connected in the form of the diode. Accordingly, a voltage obtained by subtracting the absolute threshold voltage of the first transistor M1 from the first power voltage VDD may be supplied to the third node N3. Therefore, during the second period P2, a voltage corresponding to the threshold voltage of the first transistor M1 may be stored in the second capacitor C2 (and the first capacitor C1).

Referring to FIG. 6C, during the third period P3, the enable first scan signal GW may be supplied to the first sub-gate line SGL1, the enable fourth scan signal GB may be supplied to the fourth sub-gate line SGL4, and the disable emission control signal EM may be supplied to the emission control line ELi.

When the enable fourth scan signal GB is supplied to the fourth sub-gate line SGL4, the fifth transistor M5 may be turned on. When the fifth transistor M5 is turned on, the initialization voltage VINT may be supplied to the anode electrode AE of the light-emitting element LD. Accordingly, the light-emitting element LD may be set to a non-emitting state.

When the disable emission control signal EM is supplied to the emission control line ELi, the sixth transistor M6 may be turned off. When the sixth transistor M6 is turned off, the second node N2 and the anode electrode AE of the light-emitting element LD may be electrically cut off.

When the enable first scan signal GW is supplied to the first sub-gate line SGL1, the second transistor M2 may be turned on. When the second transistor M2 is turned on, a data signal Vdata supplied to the data line DLj may be supplied to the fourth node N4.

When the data signal Vdata is supplied to the fourth node N4, a voltage of the fourth node N4 may be changed from the initialization voltage VINT to a voltage of the data signal Vdata. As this time, the voltage of the third node N3 may also be changed based on the voltage change amount of the fourth node N4 by the coupling of the first capacitor C1.

The voltage change amount of the third node N3 may be determined corresponding to the ratio of the first capacitor C1 and the second capacitor C2. In an embodiment, the voltage of the third node N3 may be changed from the voltage obtained by subtracting the absolute threshold voltage of the first transistor M1 from the first power voltage VDD to a value obtained by multiplying the voltage change amount of the fourth node N4 by C1/(C1+C2), for example. When the voltage change amount of the third node N3 is controlled by the ratio of the first capacitor C1 and the second capacitor C2, the voltage range of the data signal may be sufficiently wide.

In an embodiment, when the data signal Vdata is supplied directly to the third node N3, the voltage range of the data signal Vdata may be set to be relatively narrow, for example. In this case, various gray levels (e.g., 256 gray levels) must be implemented using a narrow voltage range, and thus it may be difficult to accurately express the gray levels in the display device 100.

When the voltage supplied to the gate electrode of the first transistor M1 is controlled by the ratio of the first capacitor C1 and the second capacitor C2 as in embodiments of the disclosure, the voltage range of the data signal may be set sufficiently wide. In other words, when a voltage corresponding to a value obtained by multiplying the voltage of the data signal by C1/(C1+C1) is supplied to the gate electrode of the first transistor M1, the voltage range of the data signal may be set wide. When the data signal has a wide voltage range, grayscale may be easily implemented in the display device 100.

Referring to FIG. 6D, the enable emission control signal EM may be supplied to the emission control line ELi during the emission period EMP after the third period P3.

When the enable emission control signal EM is supplied to the emission control line ELi, the sixth transistor M6 may be turned on. When the sixth transistor M6 is turned on, a current path leading to the second power voltage node VSSN via the first power voltage node VDDN, the first node N1, the first transistor M1, the second node N2, the sixth transistor M6, and the light-emitting element LD may be formed. In this case, the first transistor M1 may control the amount of driving current supplied from the first power voltage node VDDN to the second power voltage node VSSN in response to the voltage of the third node N3. The light-emitting element LD may generate light of a set luminance based on the amount of driving current.

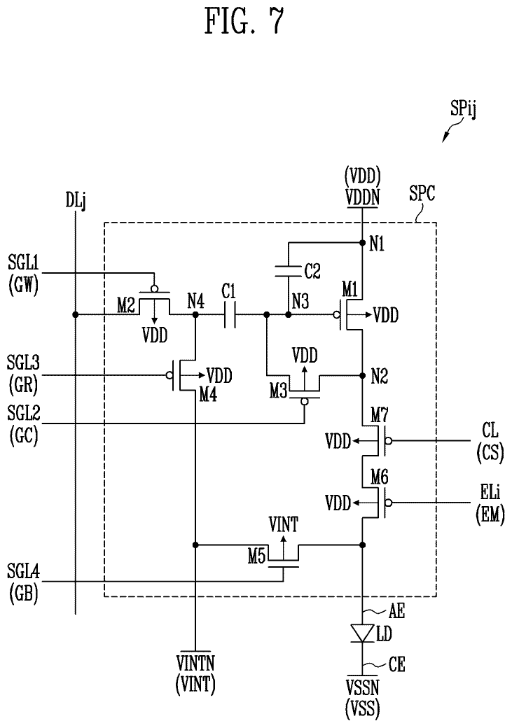

FIG. 7 is a circuit diagram illustrating an embodiment of the sub-pixel shown in FIG. 2. When describing FIG. 7, the same drawing reference numerals are assigned to the same components as those in FIG. 4, and duplicate descriptions are omitted.

Referring to FIG. 7, the sub-pixel SPij may include a sub-pixel circuit SPC and a light-emitting element LD.

The sub-pixel circuit SPC may include a first transistor M1, a second transistor M2, a third transistor M3, a fourth transistor M4, a fifth transistor M5, a sixth transistor M6, a seventh transistor M7, a first capacitor C1, and a second capacitor C2.

The seventh transistor M7 may be connected between a second node N2 and the sixth transistor M6. A gate electrode of the seventh transistor M7 may be connected to a common line CL. The seventh transistor M7 may be set a P-type transistor, and include a body electrode. A first power voltage VDD may be supplied to the body electrode.

The common line CL may be commonly connected to the sub-pixels SP formed in the display panel 110. But the disclosure is not limited thereto. In an embodiment, the display panel 110 may be divided into block units including two or more sub-pixels SP, for example. The sub-pixels SP may be connected to different common line CL in a block unit.

The common line CL may be supplied with a control signal CS from the controller 150. The control signal CS may be set to a voltage at which the seventh transistor M7 may be turned on. In other words, the seventh transistor M7 may electrically connect the second node N2 and the sixth transistor M6 while maintaining the turn-on state. In an embodiment, the seventh transistor M7 may maintain in a turn-on state during the display device 100 is driven, for example. A voltage of the control signal CS may be set to a voltage that causes the seventh transistor M7 to have a set load (or a set resistance). In an embodiment, the control signal CS may be experimentally determined such that the seventh transistor M7 has the set resistance value, for example.

When the seventh transistor M7 having the set resistance value is connected to a second electrode (or a drain electrode) of the first transistor M1, the first transistor M1 may minimize the amount of change in the amount of driving current in response to a change in the voltage (e.g., a drain-source voltage) of the drain electrode and a source electrode of the first transistor M1. In this case, the sub-pixel SPij may stably implement a desired grayscale.

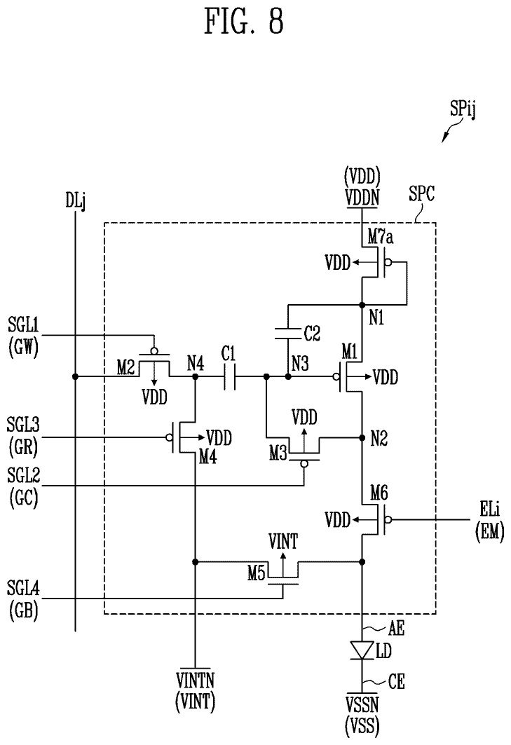

FIG. 8 is a circuit diagram illustrating an embodiment of the sub-pixel shown in FIG. 2. When describing FIG. 8, the same drawing reference numerals are assigned to the same components as those in FIG. 4, and duplicate descriptions are omitted.

Referring to FIG. 8, the sub-pixel SPij may include a sub-pixel circuit SPC and a light-emitting element LD.

The sub-pixel SPij may include a first transistor M1, a second transistor M2, a third transistor M3, a fourth transistor M4, a fifth transistor M5, a sixth transistor M6, a seventh transistor M7a, a first capacitor C1, and a second capacitor C2.

The seventh transistor M7a may be connected between a first power voltage node VDDN and a first node N1. The seventh transistor M7a may be set to a P-type transistor, and include a body electrode. A first power voltage VDD may be supplied to the body electrode. A gate electrode of the seventh transistor M7a may be connected to the first node N1. In other words, the seventh transistor M7a may be connected in the form of a diode to allow current to flow from the first power voltage node VDDN to the first node N1.

When the seventh transistor M7a is connected in the form of the diode, the change in the amount of driving current due to the threshold voltage deviation of the first transistor M1 may be minimized by source degeneration. In other words, when a resistor or a diode is connected to a source electrode of a transistor, the change in the amount of driving current due to the threshold voltage of the transistor may be minimized by source degeneration.

When each of the sub-pixels SP includes the seventh transistor M7a, the change in the amount of driving current due to the threshold voltage deviation of the first transistor M1 may be minimized. Accordingly, the display device 100 may display an image having a uniform luminance.

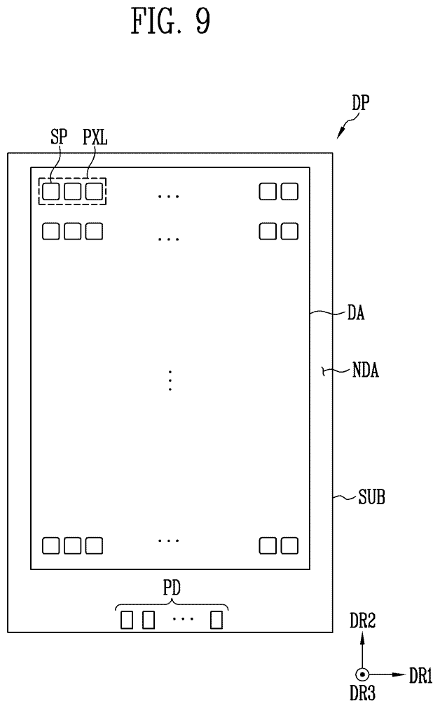

FIG. 9 is a plan view illustrating an embodiment of the display panel of FIG. 1.

Referring to FIG. 9, a display panel DP in an embodiment of the display panel 110 of FIG. 1 may include a display area DA and a non-display area NDA. The display panel DP may display an image through the display area DA. The non-display area NDA may be disposed around the display area DA.

The display panel DP may include a substrate SUB, sub-pixels SP, and pads PD.

When the display panel DP is used as the display screen of a head-mounted display (“HMD”), a virtual reality (“VR”) device, a mixed reality (“MR”) device, an augmented reality (“AR”) device or the like, the display panel DP may be disposed substantially close to a user's eyes. In this case, the sub-pixels SP with relatively high degree of integration are desired. In order to increase the degree of integration of the sub-pixels SP, the substrate SUB may be provided as a silicon substrate. The sub-pixels SP and/or the display panel DP may be formed on the substrate SUB which is a silicon substrate. The display device 100 (refer to FIG. 1) including the display panel DP formed on the substrate SUB which is a silicon substrate may be also referred to as an organic light-emitting diode on silicon (“OLEDoS”) display device.

The sub-pixels SP are disposed in the display area DA on the substrate SUB. The sub-pixels SP may be arranged in a matrix shape in a first direction DR1 and a second direction DR2 intersecting the first direction DR1. However, the disclosure is not limited thereto. In an embodiment, the sub-pixels SP may be arranged in a zigzag pattern in the first direction DR1 and the second direction DR2, for example. In an embodiment, the sub-pixels SP may be disposed in a PENTILE^{TM} pattern, for example. The first direction DR1 may be a row direction, and the second direction DR2 may be a column direction.

Two or more sub-pixels SP among the plurality of sub-pixels SP may configure one pixel PXL.

Components for controlling the sub-pixels SP may be disposed in the non-display area NDA on the substrate SUB. In an embodiment, wirings which are connected to the sub-pixels SP, such as the first to m-th gate lines GL1 to GLm and the first to n-th data lines DL1 to DLn of FIG. 1, may be disposed in the non-display area NDA, for example.

At least one of the gate driver 120, the data driver 130, the voltage generator 140, the controller 150, and the temperature sensor 160 of FIG. 1 may be integrated in the non-display area NDA of the display panel DP. In embodiments, the gate driver 120 of FIG. 1 may be disposed (e.g., mounted) in the display panel DP, and may be disposed in the non-display area NDA. In other embodiments, the gate driver 120 may be implemented as an integrated circuit which is separate from the display panel DP. In embodiments, the temperature sensor 160 may be disposed in the non-display area NDA to sense a temperature of the display panel DP.

The pads PD may be disposed in the non-display area NDA on the substrate SUB. The pads PD may be electrically connected to the sub-pixels SP via the wirings. In an embodiment, the pads PD may be connected to the sub-pixels SP through the first to n-th data lines DL1 to DLn, for example.

The pads PD may interface the display panel DP to other components of the display device 100 (refer to FIG. 1). In an embodiment, voltages and signals desired for an operation of components included in the display panel DP may be provided from the driver integrated circuit DIC of FIG. 1 through the pads PD. In an embodiment, the first to n-th data lines DL1 to DLn may be connected to the driver integrated circuit DIC through the pads PD, for example. In an embodiment, the first and second power voltages VDD and VSS may be received from the voltage generator 140 through the pads PD, for example. In an embodiment, when the gate driver 120 is disposed (e.g., mounted) in the display panel DP, the gate control signal GCS may be transmitted from the driver integrated circuit DIC to the gate driver 120 through the pads PD, for example.

In embodiments, a circuit board may be electrically connected to the pads PD using a conductive adhesive member such as an anisotropic conductive film. At this time, the circuit board may be a flexible printed circuit board (“FPCB”) or a flexible film having a flexible material. The driver integrated circuit DIC may be disposed (e.g., mounted) on the circuit board to be electrically connected to the pads PD.

In embodiments, the display area DA may have various shapes. The display area DA may have a closed loop shape including straight and/or curved sides. In an embodiment, the display area DA may have shapes such as a polygon, a circle, a semicircle and an ellipse, for example.

In embodiments, the display panel DP may have a flat display surface. In other embodiments, the display panel DP may have a display surface that is at least partially round. In embodiments, the display panel DP may be bendable, foldable or rollable. In these cases, the display panel DP and/or the substrate SUB may include materials having flexible properties.

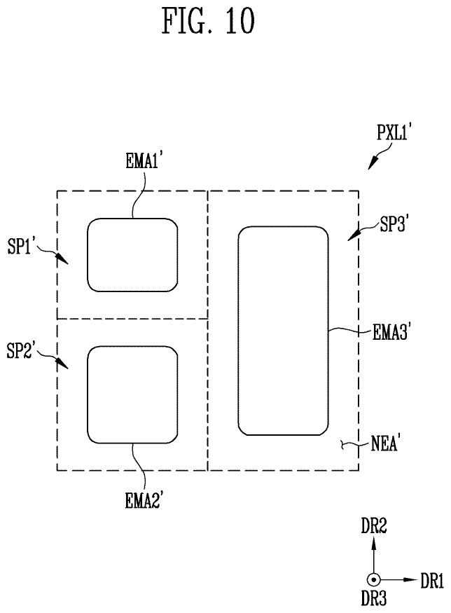

FIG. 10 is a plan view illustrating another embodiment of one of the pixels of FIG. 9.

Referring to FIG. 10, a first pixel PXL1′ may include first to third sub-pixels SP1′ to SP3′.

The first sub-pixel SP1′ may include a first emission area EMA1′, and a non-emission area NEA′ around the first emission area EMA1′. The second sub-pixel SP2′ may include a second emission area EMA2′ and a non-emission area NEA′ around the second emission area EMA2′. The third sub-pixel SP3′ may include a third emission area EMA3′ and a non-emission area NDA′ around the third emission area EMA3′.

The first sub-pixel SP1′ and the second sub-pixel SP2′ may be arranged in the second direction DR2. The third sub-pixel SP3′ may be disposed in the first direction DR1 with respect to each of the first and second sub-pixels SP1′ and SP2′.

The second sub-pixel SP2′ may have a larger area than the first sub-pixel SP1′, and the third sub-pixel SP3′ may have a larger area than the second sub-pixel SP2′. Accordingly, the second emission area EMA2′ may have a larger than the first emission area EMA1′, and the third emission area EMA3′ may have a larger area than the second emission area EMA2′. However, the disclosure is not limited thereto. In an embodiment, the first and second sub-pixels SP1′ and SP2′ may have substantially the same area as each other, and the third sub-pixel SP3′ may have a larger area than each of the first and second sub-pixels SP1′ and SP2′, for example. In this way, the areas of the first to third sub-pixels SP1′ to SP3′ may be changed in various ways in embodiments.

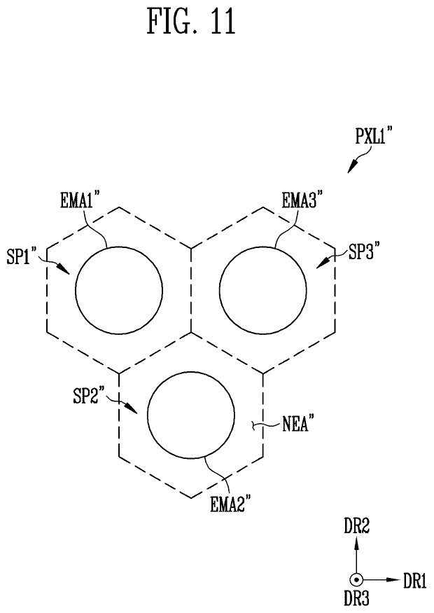

FIG. 11 is a plan view illustrating another embodiment of one of the pixels of FIG. 9.

Referring to FIG. 11, a first sub-pixel SP1″ may include a first emission area EMA1″ and a non-emission area NEA″ around the first emission area EMA1″. A second sub-pixel SP2″ may include a second emission area EMA2″ and a non-emission area NEA″ around the second emission area EMA2″. A third sub-pixel SP3″ may include a third emission area EMA3″ and a non-emission area NEA″ around the third emission area EMA3″.

The first to third sub-pixels SP1″ to SP3″ may have polygonal shapes when viewed in a third direction DR3. In an embodiment, the shapes of the first to third sub-pixels SP1″ to SP3″ may be hexagons as shown in FIG. 11, for example.

The first to third emission areas EMA1″ to EMA3″ may have circular shapes when viewed in the third direction DR3. However, the disclosure is not limited thereto. In an embodiment, each of the first to third emission areas EMA1″ to EMA3″ may have a polygonal shape, for example.

The first and third sub-pixels SP1″ and SP3″ may be arranged in the first direction DR1. The second sub-pixel SP2″ may be disposed in a direction inclined by an acute angle from the second direction DR2 (or a diagonal direction) with respect to the first-pixel SP1″.

The arrangement of the sub-pixels represents an example, and the disclosure is not limited thereto. Each pixel may include two or more sub-pixels, the sub-pixels may be arranged in various ways, each of the sub-pixels may have various shapes, and each of emission areas of the sub-pixels may also have various shapes.

The display device 100 in the embodiments may be applied to various electronic devices. An electronic device in the embodiments may include the display device 100 described above, and may further include modules or devices having an additional function other than the display device 100.

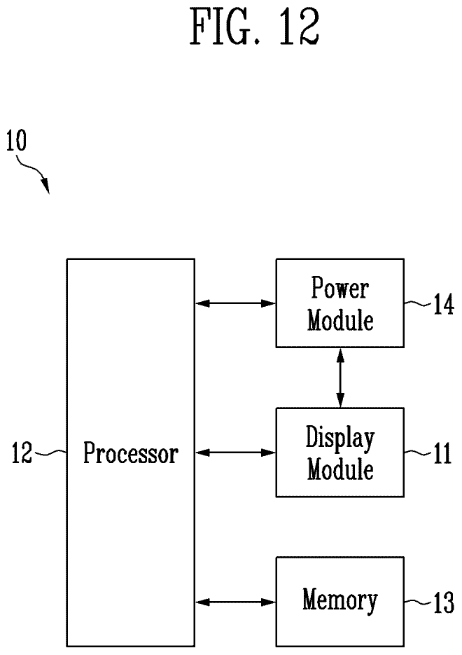

FIG. 12 is a block diagram illustrating an electronic device in embodiments of the disclosure. Referring to FIG. 12, the electronic device 10 in embodiments of disclosure may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and conversion module. The power conversion module convers power supplied by the power supply module and generates power to operate the electronic device 10.

At least one of the above-described components of the electronic device 10 may be included in the display device 100 in embodiments as described above. In addition, in terms of functionality, some of the individual modules included in one module may be included in the display device 100 and others may be provided separately from the display device. In an embodiment, the display module 11 is included in the display device 100, whereas the processor 12, the memory 13, and the power module 14 are not included in the display device 100 and are instead provided separately in the electronic device 10, for example. In an embodiment, the display module 11 may include the sub-pixels SP shown in FIG. 1, for example.

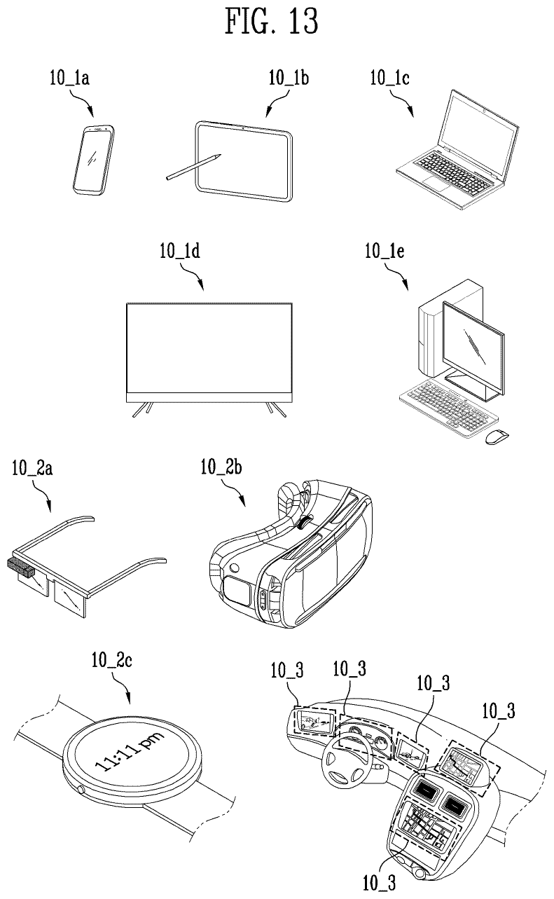

FIG. 13 shows schematic views of various embodiments of an electronic device.

Referring to FIG. 13, various types of electronic devices to which embodiments of a display device are applied may include an electronic device to display images such as a smartphone 10_1a, a tablet PC 10_1b, a laptop computer 10_1c, a television (“TV”) 10_1d, and a desktop monitor 10_1e, a wearable electronic device including a display module such as smart glasses 10_2a, a head-mounted display (“HMD”) 10_2b, and a smart watch 10_2c, and an automotive electronic device 10_3 including a display module such as a center information display (“CID”) disposed at the instrument cluster, the center fascia, and the dashboard of a vehicle, and a room mirror display.

By embodiments of the disclosure, the sub-pixel, the display device including the sub-pixel, and the electronic device may sufficiently secure the voltage range of the data signal (Data Swing Range). Accordingly, the sub-pixel, the display device including the sub-pixel and the electronic device may stably implement grayscale. In addition, in embodiments of the disclosure, the sub-pixel may be configured by six transistors and two capacitors. Accordingly, the disclosure may be applied to relatively high resolution panels.

The embodiments described above are provided to explain the disclosure, but these embodiments are not intended to limit the scope of the disclosure. It will be understood by those skilled in the art that various changes, substitutions, and alternatives may be made therein without departing from the scope of the disclosure as set forth by the claims and their equivalents. Therefore, the technical scope of the disclosure may be determined based on the scope of the accompanying claims and their functional equivalents.

What is claimed is:

1. A sub-pixel comprising:
a first transistor including:
a first electrode connected to a first power voltage node to which a first power voltage is input via a first node;
a second electrode connected to a second node; and
a gate electrode connected to a third node;
a light-emitting element including:
an anode electrode connected to the second node; and
a cathode electrode connected to a second power voltage node to which a second power voltage is input;
a second transistor connected between a data line and a fourth node, the second transistor including:
a gate electrode connected to a first sub-gate line;
a third transistor connected between the second node and the third node, the third transistor including:
a gate electrode connected to a second sub-gate line;
a fourth transistor connected between the fourth node and an initialization voltage node to which an initialization voltage is input, the fourth transistor including:
a gate electrode connected to a third sub-gate line;
a first capacitor connected between the third node and the fourth node; and
a second capacitor connected between the first node and the third node,
wherein the third transistor and the fourth transistor are simultaneously turned on and off, and
wherein a turn-on period of the second transistor and a turn-on period of the third transistor do not overlap.

2. The sub-pixel of claim 1, wherein the second sub-gate line and the third sub-gate line are a same line.

3. The sub-pixel of claim 1, further comprising:
a fifth transistor connected between the anode electrode of the light-emitting element and the initialization voltage node, the fifth transistor including a gate electrode connected to a fourth sub-gate line; and
a sixth transistor connected between the anode electrode of the light-emitting element and the second node, the sixth transistor including a gate electrode connected to an emission control line.

4. The sub-pixel of claim 3, wherein the first transistor, the second transistor, the third transistor, the fourth transistor, and the sixth transistor are a P-type transistor, and
wherein the fifth transistor is an N-type transistor.

5. The sub-pixel of claim 4, wherein each of the first transistor to the sixth transistor includes a body electrode,
wherein the first power voltage is supplied to the body electrode of the first transistor, the body electrode of the second transistor, the body electrode of the third transistor, the body electrode of the fourth transistor, and the body electrode of the sixth transistor, and
wherein the initialization voltage is supplied to the body electrode of the fifth transistor.

6. The sub-pixel of claim 3, wherein one horizontal period is divided into a first period, a second period, and a third period,
wherein the second transistor is turned on during the third period,
wherein the third transistor and the fourth transistor are turned on during the first period and the second period,
wherein the fifth transistor is turned on during the first period, the second period, and the third period, and
wherein the sixth transistor is turned on during the first period.

7. The sub-pixel of claim 6, wherein a data signal is supplied to the data line during the third period.

8. The sub-pixel of claim 3, further comprising:
a seventh transistor connected between the second node and the sixth transistor, the seventh transistor including a gate electrode connected to a common line and a body electrode to which the first power voltage is input,
wherein the seventh transistor is a P-type transistor, and
wherein the seventh transistor is maintained in a turn-on state.

9. The sub-pixel of claim 3, further comprising:
a seventh transistor connected between the first power voltage node and the first node, the seventh transistor including a gate electrode connected to the first node and a body electrode to which the first power voltage is input, and
wherein the seventh transistor is a P-type transistor.

10. The sub-pixel of claim 1, wherein the first power voltage is set to be higher than the second power voltage, and
wherein the light-emitting element is turned off by the initialization voltage when supplied to the anode electrode of the light-emitting element.

11. A display device comprising:
sub-pixels connected with data lines, gate lines, and emission control lines, at least one of the sub-pixels including:
a first transistor in which a first electrode is connected to a first power voltage node to which a first power voltage is input via a first node, a second electrode is connected to a second node, and a gate electrode is connected to a third node;
a light-emitting element in which an anode electrode is connected to the second node and a cathode electrode is connected to a second power voltage node to which a second power voltage is input;
a second transistor connected between a data line which i one of the data lines and a fourth node, the second transistor being turned on when an enable first scan signal is supplied to a first sub-gate line which is one of the gate lines;
a third transistor connected between the second node and the third node, the third transistor being turned on when an enable second scan signal is supplied to a second sub-gate line which is one of the gate lines;
a fourth transistor connected between the fourth node and an initialization voltage node to which an initialization voltage is input, the fourth transistor being turned on when an enable third scan signal is supplied to a third sub-gate line which is one of the gate lines;
a fifth transistor connected between the anode electrode of the light-emitting element and the initialization voltage node, the fifth transistor being turned on when an enable fourth scan signal is supplied to a fourth sub-gate line which is one of the gate lines;
a sixth transistor connected between the anode electrode of the light-emitting element and the second node, the sixth transistor being turned off when a disable emission control signal is supplied to an emission control line which is one of the emission control lines;
a first capacitor connected between the third node and the fourth node; and
a second capacitor connected between the first node and the third node;
a gate driver configured to drive the gate lines and the emission control lines; and
a data driver configured to drive the data lines.

12. The display device of claim 11, wherein the second sub-gate line and the third sub-gate line are a same line.

13. The display device of claim 11, wherein the first transistor, the second transistor, the third transistor, the fourth transistor, and the sixth transistor are a P-type transistor, and
wherein the fifth transistor is an N-type transistor.

14. The display device of claim 13, wherein each of the first transistor to the sixth transistor includes a body electrode,
wherein the first power voltage is supplied to the body electrode of the first transistor, the body electrode of the second transistor, the body electrode of the third transistor, the body electrode of the fourth transistor, and the body electrode of the sixth transistor, and
wherein the initialization voltage is supplied to the body electrode of the fifth transistor.

15. The display device of claim 11, wherein one horizontal period is divided into a first period, a second period, and a third period,
wherein the gate driver supplies the enable first scan signal to the first sub-gate line during the third period,
wherein the gate driver supplies the enable second scan signal to the second sub-gate line during the first period and the second period, and supplies the enable third scan signal to the third sub-gate line during the first period and the second period,
wherein the gate driver supplies the enable fourth scan signal to the fourth sub-gate line during the first period, the second period, and the third period, and
wherein the gate driver supplies the disable emission control signal to the emission control line during the second period and the third period.

16. The display device of claim 15, wherein the data driver supplies a data signal to the data line during the third period.

17. The display device of claim 11, further comprising:
a seventh transistor connected between the second node and the sixth transistor, the seventh transistor including a gate electrode connected to a common line and a body electrode to which the first power voltage is input,
wherein the seventh transistor is a P-type transistor, and
wherein the seventh transistor is maintained in a turn-on state by a control signal supplied to the common line.

18. The display device of claim 17, wherein the common line is commonly connected to the sub-pixels.

19. The display device of claim 11, further comprising:
a seventh transistor connected between the first power voltage node and the first node, the seventh transistor including a gate electrode connected to the first node and a body electrode to which the first power voltage is input, and
wherein the seventh transistor is a P-type transistor.

20. An electronic device comprising:
a processor;
a display module configured to display an image based on input image data supplied from the processor, the display module including:
sub-pixels connected with data lines, gate lines, and emission control lines, at least one of the sub-pixels including:
a first transistor in which a first electrode is connected to a first power voltage node to which a first power voltage is input via a first node, a second electrode is connected to a second node, and a gate electrode is connected to a third node;
a light-emitting element in which an anode electrode is connected to the second node and a cathode electrode is connected to a second power voltage node to which a second power voltage is input;
a second transistor connected between a data line which is one of the data lines and a fourth node, the second transistor being turned on when an enable first scan signal is supplied to a first sub-gate line which is one of the gate lines;
a third transistor connected between the second node and the third node, the third transistor being turned on when an enable second scan signal is supplied to a second sub-gate line which is one of the gate lines;
a fourth transistor connected between the fourth node and an initialization voltage node to which an initialization voltage is input, the fourth transistor being turned on when an enable third scan signal is supplied to a third sub-gate line which is one of the gate lines;
a fifth transistor connected between the anode electrode of the light-emitting element and the initialization voltage node, the fifth transistor being turned on when an enable fourth scan signal is supplied to a fourth sub-gate line which is one of the gate lines;
a sixth transistor connected between the anode electrode of the light-emitting element and the second node, the sixth transistor being turned off when a disable emission control signal is supplied to an emission control line which is one of the emission control lines;
a first capacitor connected between the third node and the fourth node; and
a second capacitor connected between the first node and the third node;
a gate driver configured to drive the gate lines and emission control lines; and
a data driver configured to drive the data lines;
a memory in which data information for an operation of the processor is stored; and
a power module configured to generate power for driving.
